(19) United States
(12) Patent Application Publication
(10) Pub. No.: US 2023/0130677 A1
(43) Pub. Date: Apr. 27, 2023

(54) HEAT-DISSIPATION SUBSTRATE HAVING GRADIENT SPUTTERED STRUCTURE

(71) Applicant: AMULAIRE THERMAL TECHNOLOGY, INC., New Taipei City (TW)

(72) Inventors: MIN-HORNG LIU, New Taipei City (TW); TZE-YANG YEH, New Taipei City (TW)

(21) Appl. No.: 17/507,764

(22) Filed: Oct. 21, 2021

(51) Int. Cl. F28F 21/08

(52) U.S. Cl. CPC F28F 21/089

(57) ABSTRACT

A heat-dissipation substrate having a gradient sputtered structure includes at least two layers. A first layer is a heat-dissipation base layer, and a second layer is a gradient sputtered layer that is bonded onto the heat-dissipation base layer by gradient sputtering. An outermost surface layer of the gradient sputtered layer is a functional layer, and the gradient sputtered layer contains a main component of the heat-dissipation base layer and that of the functional layer. A percentage of the main component of the functional layer contained in the gradient sputtered layer monotonically increases or strictly monotonically increases along a direction from the heat-dissipation base layer toward the functional layer, and a percentage of the main component of the heat-dissipation base layer contained in the gradient sputtered layer monotonically increases or strictly monotonically increases along a direction from the functional layer toward the heat-dissipation base layer.

### FIELD OF THE DISCLOSURE

The present disclosure relates to a heat-dissipation substrate, and more particularly to a heat-dissipation substrate having a gradient sputtered structure.

### BACKGROUND OF THE DISCLOSURE

Generally, a sputtered metal layer is formed on a surface of a conventional heat-dissipation substrate, so as to increase functional properties provided by said surface. However, since the heat-dissipation substrate and the sputtered metal layer are formed by different metals, a bonding strength between the sputtered metal layer and the heat-dissipation substrate is not high, thereby causing a product life to decrease significantly.

### SUMMARY OF THE DISCLOSURE

In response to the above-referenced technical inadequacies, the present disclosure provides a heat-dissipation substrate having a gradient sputtered structure.

In one aspect, the present disclosure provides a heat-dissipation substrate having a gradient sputtered structure. The heat-dissipation substrate includes at least two layers. A first layer is a heat-dissipation base layer, a second layer is a gradient sputtered layer, and the gradient sputtered layer is bonded onto the heat-dissipation base layer by gradient sputtering. An outermost surface layer of the gradient sputtered layer is a functional layer, and the gradient sputtered layer contains a main component of the heat-dissipation base layer and a main component of the functional layer. A percentage of the main component of the functional layer contained in the gradient sputtered layer monotonically increases or strictly monotonically increases along a direction from the heat-dissipation base layer toward the functional layer, and a percentage of the main component of the heat-dissipation base layer contained in the gradient sputtered layer monotonically increases or strictly monotonically increases along a direction from the functional layer toward the heat-dissipation base layer.

In one exemplary embodiment, the main component of the heat-dissipation base layer is one of aluminum, aluminum alloy, copper, and copper alloy.

In one exemplary embodiment, the main component of the functional layer is one of aluminum, aluminum alloy, nickel, nickel alloy, copper, copper alloy, silver, and silver alloy.

In one exemplary embodiment, the outermost surface layer of the gradient sputtered layer is the functional layer that is configured to contain 90% to 95% of the main component of the functional layer and 10% to 5% of the main component of the heat-dissipation base layer.

In one exemplary embodiment, a thickness of the gradient sputtered layer is controlled to be between 50 nm and 10 um.

In one exemplary embodiment, a thickness precision of the gradient sputtered layer is ±0.2 um.

In one exemplary embodiment, the heat-dissipation base layer is immersed in a two-phase coolant, and is configured as a liquid-cooling heat sink having a porosity greater than 5%.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a heat-dissipation substrate having a gradient sputtered structure according to the present disclosure;

FIG. 2 is a schematic diagram showing a percentage of a main component increasing monotonically according to the present disclosure; and

FIG. 3 is a schematic diagram showing the percentage of the main component increasing strictly monotonically according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

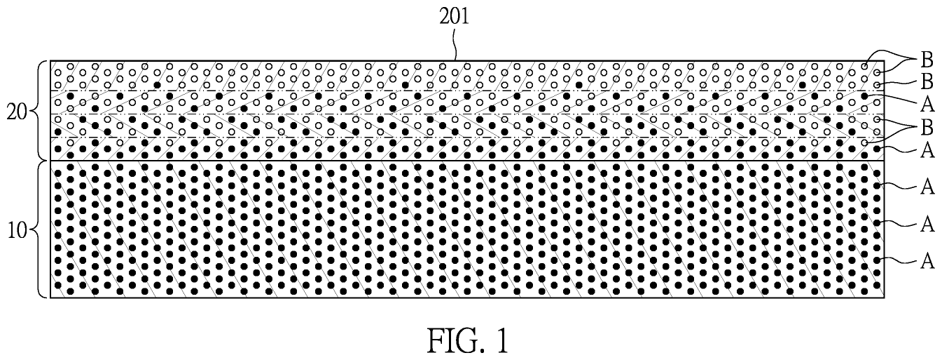

Referring to FIG. 1, an embodiment of the present disclosure provides a heat-dissipation substrate having a gradient sputtered structure. As shown in the drawing, in the embodiment of the present disclosure, the heat-dissipation substrate having the gradient sputtered structure includes at least two layers.

A first layer is a heat-dissipation base layer 10. The heat-dissipation base layer 10 can be formed by at least one of aluminum, aluminum alloy, copper, and copper alloy. That is to say, a main component A of the heat-dissipation base layer 10 can be one of aluminum, aluminum alloy, copper, and copper alloy.

A second layer is a gradient sputtered layer 20, and the gradient sputtered layer 20 is bonded onto the heat-dissipation base layer 10 by gradient sputtering. An outermost surface layer of the gradient sputtered layer 20 is a functional layer 201, which has an anti-corrosion property, a soldering property, or a sintering property. The functional layer 201 can be formed by at least one of aluminum, aluminum alloy, nickel, nickel alloy, copper, copper alloy, silver, and silver alloy. That is to say, a main component B of the functional layer 201 can be one of aluminum, aluminum alloy, nickel, nickel alloy, copper, copper alloy, silver, and silver alloy.

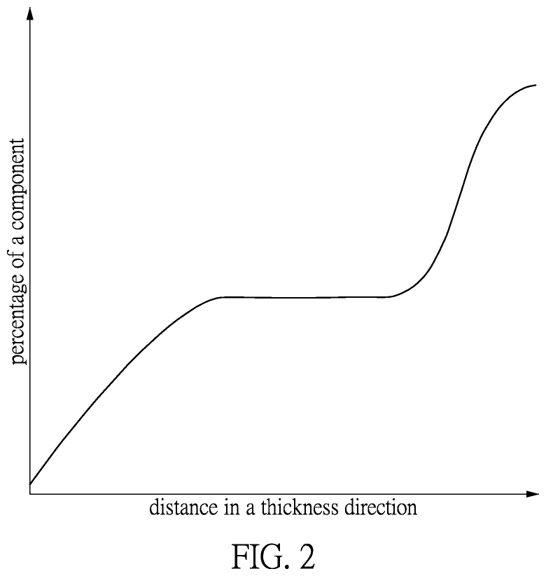

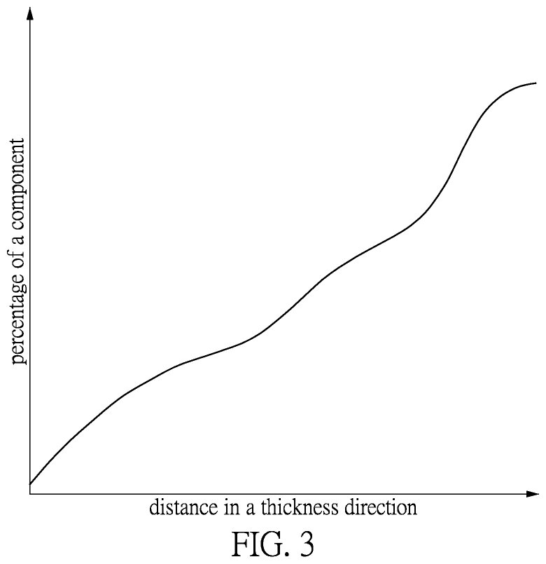

More specifically, the gradient sputtered layer 20 contains the main component A of the above-mentioned heat-dissipation base layer 10 and the main component B of the above-mentioned functional layer 201. In addition, a percentage of the main component B of the functional layer 201 contained in the gradient sputtered layer 20 monotonically increases or strictly monotonically increases along a direction from the heat-dissipation base layer 10 toward the functional layer 201, and a percentage of the main component A of the heat-dissipation base layer 10 contained in the gradient sputtered layer 20 monotonically increases (a manner by which the percentage increases is as shown in FIG. 2) or strictly monotonically increases (a manner by which the percentage increases is as shown in FIG. 3) along a direction from the functional layer 201 toward the heat-dissipation base layer 10. It should be noted that, in the present embodiment, the main component A and the main component B are shown in FIG. 1 in an exaggerated or enlarged manner to facilitate a better understanding of the present disclosure.

In one exemplary embodiment, the heat-dissipation base layer 10 is formed by copper. The main component B of the functional layer 201 contained in the gradient sputtered layer 20 is nickel, and the main component A of the heat-dissipation base layer 10 contained in the gradient sputtered layer 20 is copper. In addition, a percentage of nickel monotonically increases or strictly monotonically increases along the direction from the heat-dissipation base layer 10 toward the functional layer 201, and a percentage of copper monotonically increases or strictly monotonically increases along the direction from the functional layer 201 toward the heat-dissipation base layer 10. Accordingly, in the outermost surface layer (i.e., the functional layer 201) of the gradient sputtered layer 20, the percentage of nickel can be from 90% to 95%, and the percentage of copper can be from 10% to 5%. Further, in a bonding layer formed by the gradient sputtered layer 20 and the heat-dissipation base layer 10, the percentage of nickel can be from 10% to 5%, and the percentage of copper can be from 90% to 95%. In this way, the gradient sputtered layer 20 can effectively enhance its bonding ability with the heat-dissipation base layer 10, and the anti-corrosion property can be effectively improved at the same time.

In one exemplary embodiment, the heat-dissipation base layer 10 is formed by aluminum. The main component B of the functional layer 201 contained in the gradient sputtered layer 20 is copper, and the main component A of the heat-dissipation base layer 10 contained in the gradient sputtered layer 20 is aluminum. In addition, a percentage of copper monotonically increases or strictly monotonically increases along the direction from the heat-dissipation base layer 10 toward the functional layer 201, and a percentage of aluminum monotonically increases or strictly monotonically increases along the direction from the functional layer 201 toward the heat-dissipation base layer 10. Accordingly, in the outermost surface layer (i.e., the functional layer 201) of the gradient sputtered layer 20, the percentage of copper can be from 90% to 95%, and the percentage of aluminum can be from 10% to 5%. Further, in the bonding layer formed by the gradient sputtered layer 20 and the heat-dissipation base layer 10, the percentage of copper can be from 10% to 5%, and the percentage of aluminum can be from 90% to 95%. In this way, the gradient sputtered layer 20 can effectively enhance its bonding ability with the heat-dissipation base layer 10, and the soldering property can be effectively improved at the same time.

In one exemplary embodiment, the heat-dissipation base layer 10 is formed by copper alloy. The main component B of the functional layer 201 contained in the gradient sputtered layer 20 is silver alloy, and the main component A of the heat-dissipation base layer 10 contained in the gradient sputtered layer 20 is copper alloy. In addition, a percentage of silver alloy monotonically increases or strictly monotonically increases along the direction from the heat-dissipation base layer 10 toward the functional layer 201, and a percentage of copper alloy monotonically increases or strictly monotonically increases along the direction from the functional layer 201 toward the heat-dissipation base layer 10. In this way, the gradient sputtered layer 20 can effectively enhance its bonding ability with the heat-dissipation base layer 10, and the sintering property can be effectively improved at the same time. Moreover, a thickness of the gradient sputtered layer 20 formed by gradient sputtering is extremely thin. The thickness can be between 50 nm and 10 um, and a thickness precision can be ±0.2 um.

Further, the heat-dissipation base layer 10 is immersed in a two-phase coolant, and is configured as a liquid-cooling heat sink having a porosity greater than 5%.

In conclusion, in the heat-dissipation substrate having the gradient sputtered structure provided by the present disclosure, by virtue of “the heat-dissipation substrate having the gradient sputtered structure including at least two layers, in which the first layer is a heat-dissipation base layer, the second layer is a gradient sputtered layer, and the gradient sputtered layer is bonded onto the heat-dissipation base layer by gradient sputtering”, “the outermost surface layer of the gradient sputtered layer being a functional layer, and the gradient sputtered layer containing a main component of the heat-dissipation base layer and a main component of the functional layer”, and “a percentage of the main component of the functional layer contained in the gradient sputtered layer monotonically increasing or strictly monotonically increasing along a direction from the heat-dissipation base layer toward the functional layer, and a percentage of the main component of the heat-dissipation base layer contained in the gradient sputtered layer monotonically increasing or strictly monotonically increasing along a direction from the functional layer toward the heat-dissipation base layer”, the gradient sputtered layer can enhance its bonding ability with the heat-dissipation base layer and its functional properties at the same time. In addition, a service life of a product thereof can be significantly increased.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A heat-dissipation substrate having a gradient sputtered structure, comprising:
at least two layers, wherein a first layer is a heat-dissipation base layer, a second layer is a gradient sputtered layer, and the gradient sputtered layer is bonded onto the heat-dissipation base layer by gradient sputtering;
wherein an outermost surface layer of the gradient sputtered layer is a functional layer, and the gradient sputtered layer contains a main component of the heat-dissipation base layer and a main component of the functional layer;
wherein a percentage of the main component of the functional layer contained in the gradient sputtered layer monotonically increases or strictly monotonically increases along a direction from the heat-dissipation base layer toward the functional layer, and a percentage of the main component of the heat-dissipation base layer contained in the gradient sputtered layer monotonically increases or strictly monotonically increases along a direction from the functional layer toward the heat-dissipation base layer.

2. The heat-dissipation substrate according to claim 1, wherein the main component of the heat-dissipation base layer is one of aluminum, aluminum alloy, copper, and copper alloy.

3. The heat-dissipation substrate according to claim 2, wherein the main component of the functional layer is one of aluminum, aluminum alloy, nickel, nickel alloy, copper, copper alloy, silver, and silver alloy.

4. The heat-dissipation substrate according to claim 3, wherein the outermost surface layer of the gradient sputtered layer is the functional layer that is configured to contain 90% to 95% of the main component of the functional layer and 10% to 5% of the main component of the heat-dissipation base layer.

5. The heat-dissipation substrate according to claim 1, wherein a thickness of the gradient sputtered layer is controlled to be between 50 nm and 10 um.

6. The heat-dissipation substrate according to claim 5, wherein a thickness precision of the gradient sputtered layer is ±0.2 um.

7. The heat-dissipation substrate according to claim 1, wherein the heat-dissipation base layer is immersed in a two-phase coolant, and is configured as a liquid-cooling heat sink having a porosity greater than 5%.
